(19) United States
(12) Patent Application Publication
(10) Pub. No.: US 2012/0236517 A1
(43) Pub. Date: Sep. 20, 2012

(54) ELECTRONIC APPARATUS

(75) Inventor: YUJI NAKAJIMA, Nishitama-gun (JP)

(73) Assignee: KABUSHIKI KAISHA TOSHIBA, Tokyo (JP)

(21) Appl. No.: 13/326,079

(22) Filed: Dec. 14, 2011

(30) Foreign Application Priority Data
Mar. 18, 2011 (JP) 2011-061541

(51) Int. Cl. H05K 5/02

(52) U.S. Cl. 361/752

(57) ABSTRACT

According to one embodiment, an electronic apparatus includes a circuit board, a first member, and a second member. The circuit board includes a connector. The first member includes a first wall, a second wall, and a third wall. The first wall includes an operation surface, a first end, and a second end opposite to the first end. The second wall extends from the first end and includes an area configured to expose the connector. The third wall extends from the second end and faces the second wall. The second member includes a fourth wall and fifth wall. The fourth wall faces the first wall. The fifth wall extends from an end of the fourth wall toward the first wall. The circuit board is between the first wall and the fourth wall.

### CROSS-REFERENCE TO RELATED APPLICATIONS

This application is based upon and claims the benefit of priority from prior Japanese Patent Application No. 2011-061541, filed Mar. 18, 2011, the entire contents of which are incorporated herein by reference.

### FIELD

Embodiments described herein relate generally to electronic apparatuses.

### BACKGROUND

In some electronic apparatuses, a housing is divided into a lower cover and an upper cover. The lower cover includes a bottom wall and a peripheral wall rising from the periphery of the bottom wall and has a box shape with an open top. The upper cover has a plate shape and forms the upper wall of the housing.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of an electronic apparatus according to a first embodiment;

FIG. 2 is an exemplary partially exploded perspective view of the electronic apparatus shown in FIG. 1;

FIG. 3 is an exemplary perspective view of an upper cover shown in FIG. 2;

FIG. 4 is an exemplary enlarged perspective view of a side surface portion of the upper cover shown in FIG. 3;

FIG. 5 is an exemplary cross-sectional view of the electronic apparatus shown in FIG. 1;

FIG. 6 is an exemplary perspective view schematically illustrating a method of manufacturing the upper cover shown in FIG. 3;

FIG. 7 is an exemplary side view of the electronic apparatus shown in FIG. 1;

FIG. 8 is an exemplary side view schematically illustrating a side surface portion of a housing shown in FIG. 7;

FIG. 9 is an exemplary side view schematically illustrating a first modification of the side surface portion of the housing shown in FIG. 7;

FIG. 10 is an exemplary side view schematically illustrating a second modification of the side surface portion of the housing shown in FIG. 7;

FIG. 11 is an exemplary perspective view of an electronic apparatus according to a second embodiment;

FIG. 12 is an exemplary exploded perspective view of the electronic apparatus shown in FIG. 11;

FIG. 13 is an exemplary perspective view schematically illustrating a method of manufacturing an upper cover shown in FIG. 12;

FIG. 14 is an exemplary perspective view of a television according to a third embodiment;

FIG. 15 is an exemplary perspective view of an electronic apparatus related to the first embodiment;

FIG. 16 is an exemplary partially exploded perspective view of the electronic apparatus shown in FIG. 14; and

FIG. 17 is an exemplary side view of the electronic apparatus shown in FIG. 14.

### DETAILED DESCRIPTION

Various embodiments will be described hereinafter with reference to the accompanying drawings.

In general, according to one embodiment, an electronic apparatus comprises a circuit board, a first member, and a second member. The circuit board comprises a connector. The first member comprises a first wall, a second wall, and a third wall. The first wall comprises an operation surface, a first end, and a second end opposite to the first end. The second wall extends from the first end and comprises an area configured to expose the connector. The third wall extends from the second end and faces the second wall. The second member comprises a fourth wall and fifth wall. The fourth wall faces the first wall. The fifth wall extends from an end of the fourth wall toward the first wall. The circuit board is between the first wall and the fourth wall.

Hereinafter, embodiments will be described with reference to the drawings.

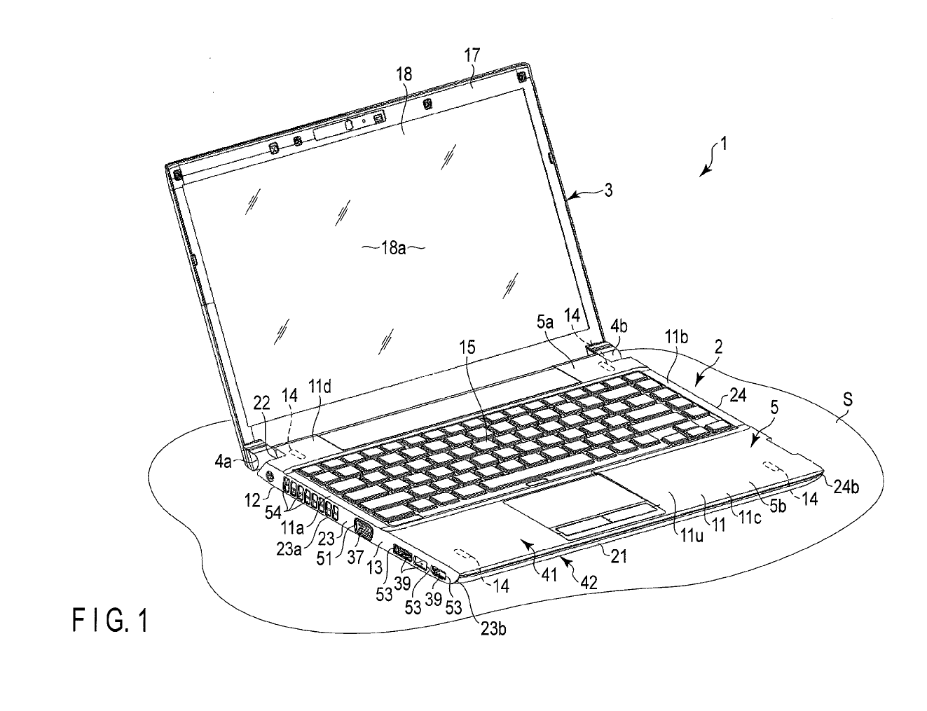

FIGS. 1 to 10 show an electronic apparatus 1 according to a first embodiment. The electronic apparatus 1 is, for example, a notebook portable computer (notebook PC). Electronic apparatuses to which this embodiment can be applied are not limited thereto. This embodiment can be widely applied to various kinds of electronic apparatuses including, for example, a television, a mobile phone, a smart phone, an electronic book terminal, and a game machine.

As shown in FIG. 1, the electronic apparatus 1 includes a first unit 2, a second unit 3, and hinge portions 4a and 4b. The first unit 2 is a main unit provided with, for example, a main board. The first unit 2 includes a first housing 5. The first housing 5 has a flat box shape including an upper wall 11, a lower wall 12, and a peripheral wall 13.

The lower wall 12 faces a desk surface S when the electronic apparatus 1 is placed on a desk. For example, a plurality of leg portions 14 that comes into contact with the desk surface S is provided on the lower wall 12. The upper wall 11 is opposite to the lower wall 12 with a space therebetween and extends substantially in parallel to the lower wall 12. An input portion 15 (i.e., input receiving portion) is provided on the upper wall 11. An example of the input portion 15 is a keyboard. The input portion 15 is not limited thereto, and it may be a touch panel or other input devices.

The peripheral wall 13 connects the peripheral edge of the lower wall 12 and the peripheral edge of the upper wall 11. One or both of the lower wall 12 and the upper wall 11 may be curved toward the peripheral wall 13 and may be connected in a substantially arc shape to the peripheral wall 13.

As shown in FIG. 1, the second unit 3 is, for example, a display unit and includes a second housing 17 and a display device 18 provided in the second housing 17. The display device 18 is, for example, a liquid crystal display, but is not limited thereto. The display device 18 includes a display screen 18a that displays a video or an image.

The second housing 17 is rotatably (openably) connected to the first housing 5 by the hinge portions 4a and 4b. In this way, the second unit 3 can be rotated between a first position where the first unit 2 and the second unit 3 overlap each other and a second position where the first unit 2 and the second unit 3 are opened. At the second position, the input portion 15 of the first unit 2 and the display screen 18a of the second unit 3 are exposed to the outside of the electronic apparatus 1.

Next, the first unit 2 will be described in detail. For convenience of explanation, hereinafter, the “first housing 5” is simply referred to as a “housing 5”.

As shown in FIG. 1, the housing 5 includes a rear end 5a connected to the second unit 3 and a front end 5b opposite to the rear end 5a. In the specification, the side close to the user of the electronic apparatus 1 is defined as the “front side” and the side away from the user is defined as the “rear side”. In addition, the left and right sides are defined in the viewing direction of the user of the electronic apparatus 1.

The peripheral wall 13 includes a front wall 21, a rear wall 22, a first side wall 23 (for example, a left wall), and a second side wall 24 (for example, a right wall). The front wall 21 is disposed in the front end 5a of the housing 5 and extends in the lateral direction (left-right direction) of the housing 5. The rear wall 22 is disposed in the rear end 5b of the housing 5 and extends in the lateral direction of the housing 5 so as to be substantially parallel to the front wall 21. Each of the first and second side walls 23 and 24 extends in the depth direction (front-rear direction) of the housing 5. The first side wall 23 connects the left end of the front wall 21 and the left end of the rear wall 22. The second side wall 24 connects the right end of the front wall 21 and the right end of the rear wall 22.

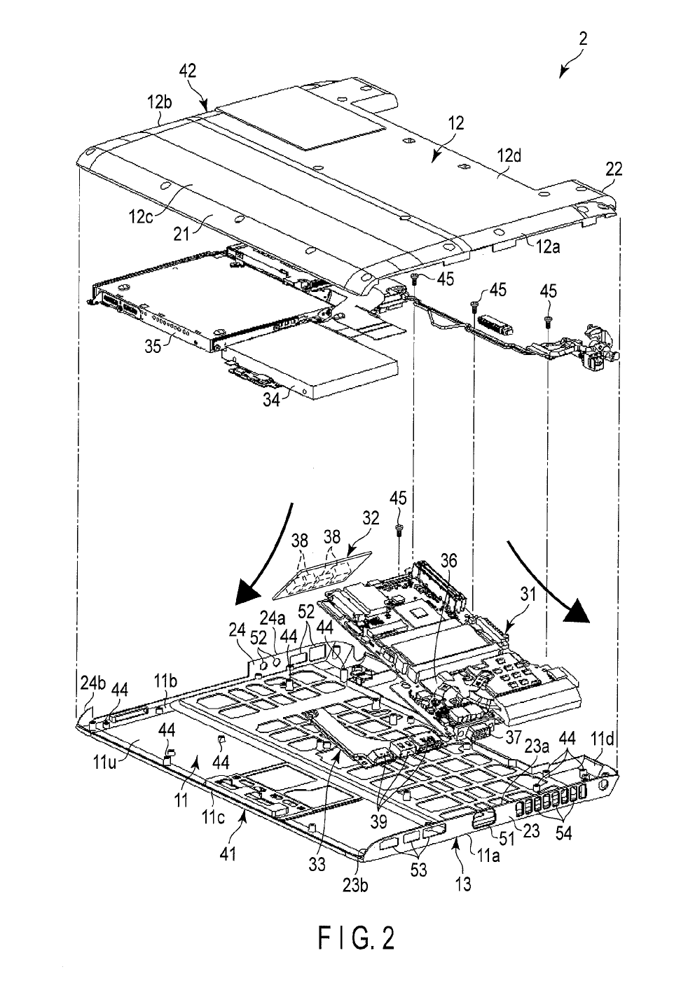

FIG. 2 is a partially exploded perspective view of the first unit 2 which is turned upside down. As shown in FIG. 2, first to third circuit boards 31, 32, and 33 and a plurality of units 34 and 35 are provided in the housing 5. For example, the first to third circuit boards 31, 32, and 33 are separately formed and can be independently attached to the housing 5. The size of each of the first to third circuit boards 31, 32, and 33 is less than that of the lower wall 12 and is less than that of the upper wall 11.

The first circuit board 31 is, for example, a main board and is provided in the left end portion of the housing 5. The first circuit board 31 includes a plurality of electronic components including a heating body 36 (i.e., heat-generating component) and a first connector 37. The heating body 36 is, for example, a CPU. The first connector 37 is, for example, an RGB serial connector.

The second circuit board 32 is provided in the right end portion of the housing 5. The second circuit board 32 includes a plurality of second connectors 38. The connector 38 is, for example, any one of a USB connector, a LAN connector (for example, an RJ45 connector), a voice input connector, and a voice output connector.

The third circuit board 33 is provided in the left end portion of the housing 5. The third circuit board 33 includes a plurality of third connectors 39. The connector 38 is, for example, a USB connector or an external serial ATA (eSATA) connector. The heating body and the connectors mounted on the first to third circuit boards 31, 32, and 33 are not limited to the above.

The plurality of units 34 and 35 include, for example, a hard disk drive 34 (HDD 34) and an optical disk drive 35 (ODD 35). The “units” provided in the housing 5 are not limited to the above, and other components may be provided in the housing 5.

Next, the structure of the housing 5 will be described in detail.

As shown in FIG. 2, the housing 5 is mainly divided into an upper cover 41 (first cover) and a lower cover 42 (second cover). The upper cover 41 is a so-called upper housing and is an example of a “first member”. The lower cover 42 is a so-called lower housing (base) and is an example of a “second member”.

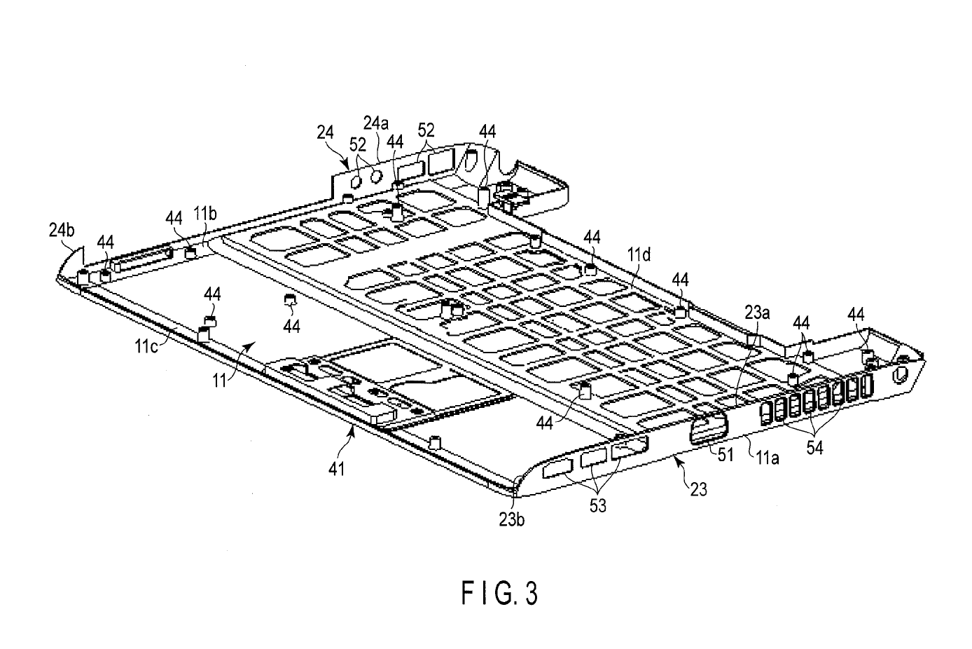

As shown in FIGS. 2 and 3, the upper cover 41 includes the upper wall 11, the first side wall 23, the second side wall 24, and a portion of the rear wall 22. The upper wall 11 is an example of a “first wall”. As shown in FIG. 1, the input portion 15 is provided on an upper surface 11u of the upper wall 11 and can receive an input from the user. The upper surface 11u of the upper wall 11 is an example of an “operation surface”. A palm rest is provided on the upper wall 11.

As shown in FIG. 1, the upper wall 11 includes a left end 11a, a right end 11b, a front end 11c, and a rear end 11d. The left end 11a is an example of a “first end”. The right end 11b is an example of a “second end” and is opposite to the left end 11a. The left end 11a extends substantially in parallel to the right end 11b.

The front end 11c and the rear end 11d extend in a direction (for example, a direction substantially perpendicular to) intersecting the left end 11a and the right end 11b. The front end 11c is an example of a “third end” and extends between the front edge of the left end 11a and the front edge of the right end 11b. The rear end 11d is an example of a “fourth end” and is opposite to the front end 11c. The rear end 11d extends between the rear edge of the left end 11a and the rear edge of the right end 11b.

The upper wall 11 has a substantially rectangular shape. The left end 11a and the right end 11b are arranged along the short sides of the upper wall 11. The front end 11c and the rear end 11d are arranged in the longitudinal direction of the upper wall 11. The leading end of each of the left end 11a, the right end 11b, the front end 11c, and the rear end 11d of the upper wall 11 is bent toward the lower wall 12 in order to improve, for example, the appearance of the peripheral edge of the upper wall 11.

As shown in FIG. 3, the upper wall 11 includes an inner surface exposed to the inside of the housing 5. A plurality of bosses 44 are provided on the inner surface of the upper wall 11. The boss 44 is an example of an “attachment portion”. The bosses 44 protrude from the inner surface of the upper wall 11 toward the lower wall 12. An engaging hole facing the lower wall 12 is provided at the leading end of the boss 44. An example of the engaging hole is a screw hole. The first to third circuit boards 31, 32, and 33 and the units 34 and 35 are attached to the bosses 44 by, for example, screws 45 and are supported by the upper wall 11.

The first side wall 23 is an example of a “second wall”. The first side wall 23 extends from the left end 11a of the upper wall 11 to a left end 12a of the lower wall 12 and is adjacent (for example, connected) to the left end 12a of the lower wall 12. The first side wall 23 extends in a direction crossing (for example, substantially perpendicular to) the upper wall 11, for example. For example, the first side wall 23 is provided over substantially the entire length of the left end 11a of the upper wall 11.

The first side wall 23 includes a lower end 23a adjacent to the lower wall 12 and a front end 23b that extends between the lower wall 12 and the upper wall 11. The front end 23b extends in the direction crossing the lower end 23a. The lower end 23a is an example of the first end of the first side wall 23. The front end 23b is an example of the second end of the first side wall 23.

The second side wall 24 is an example of a “third wall”. The second side wall 24 extends from the right end 11b of the upper wall 11 to a right end 12b of the lower wall 12 and is adjacent (for example, connected) to the right end 12b of the lower wall 12. For example, the second side wall 24 extends in a direction crossing (for example, substantially perpendicular to) the upper wall 11. For example, the second side wall 24 is provided over substantially the entire length of the right end 11b of the upper wall 11.

The second side wall 24 includes a lower end 24a adjacent to the lower wall 12 and a front end 24b that extends between the lower wall 12 and the upper wall 11. The front end 24b extends in a direction crossing the lower end 24a. The lower end 24a is an example of the first end of the second side wall 24. The front end 24b is an example of the second end of the second side wall 24. The first and second side walls 23 and 24 extend substantially in parallel and face each other.

As shown in FIG. 3, in the upper cover 41, no wall is provided between the front end 23b of the first side wall 23 and the front end 24b of the second side wall 24. That is, the upper cover 41 is opened between the first side wall 23 and the second side wall 24 in the direction along the inner surface of the upper wall 11. That is, the upper cover 41 has a portal shape that includes the upper wall 11 and the first and second side walls 23 and 24 provided at both ends of the upper wall 11 and has an open front side.

As shown in FIG. 3, first to third openings 51, 52, and 53 and exhaust holes 54 are provided in the housing 5. The first to third opening 51, 52, and 53 and the exhaust holes 54 are through holes provided in the outer wall of the housing 5 and are exposed to the outside of the housing 5. Each of the first to third openings 51, 52, and 53 is an example of an “opening area” and is also an example of an “area through which a connector is exposed”. Each of the “opening area” and the “area through which a connector is exposed” is not limited to the opening, and may be a cutout portion formed along at least a portion of the outward shape of the connector, for example.

As shown in FIGS. 1 and 2, the first opening 51 is provided in the first side wall 23 so as to correspond to the first connector 37. The first connector 37 is inserted into the first opening 51 and is exposed from the first opening 51 to the outside of the housing 5. The second openings 52 are provided in the second side wall 24 so as to correspond to the second connectors 38. The second connector 38 is inserted into the second opening 52 and is exposed from the second opening 52 to the outside of the housing 5.

The third openings 53 are provided in the first side wall 23 so as to correspond to the third connectors 39. The third connector 39 is inserted into the third opening 53 and is exposed from the third opening 53 to the outside of the housing 5. The exhaust holes 54 are provided in, for example, the first side wall 23. The exhaust holes 54 are openings for exhausting heated air in the housing 5 to the outside of the housing 5. The exhaust holes 54 may be provided in the second side wall 24.

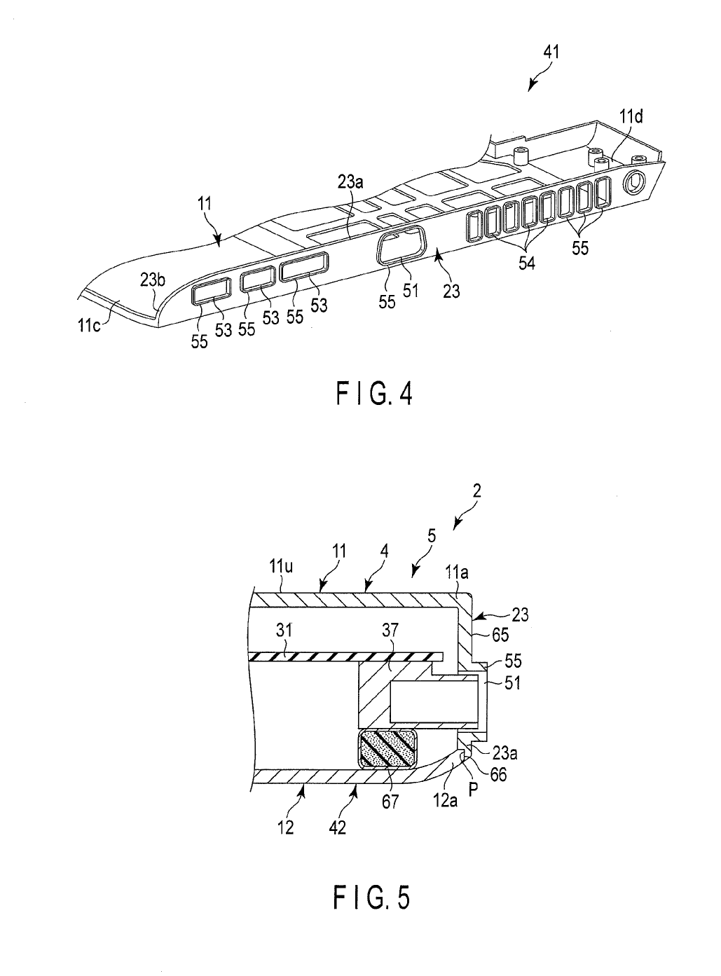

As shown in FIGS. 4 and 5, protrusions 55 protruding toward the outside of the housing 5 are provided around the first to third openings 51, 52, and 53 and the exhaust holes 54. The protrusions 55 are provided along the circumferences of the openings 51, 52, and 53 and the exhaust holes 54 and have, for example, a cylindrical shape. The protrusions 55 protrude from the first and second side walls 23 and 24 and reinforce the openings 51, 52, and 53 and the exhaust holes 54. The “protrusion” provided on the housing 5 is not limited to the above, and various kinds of protrusions may be appropriately provided.

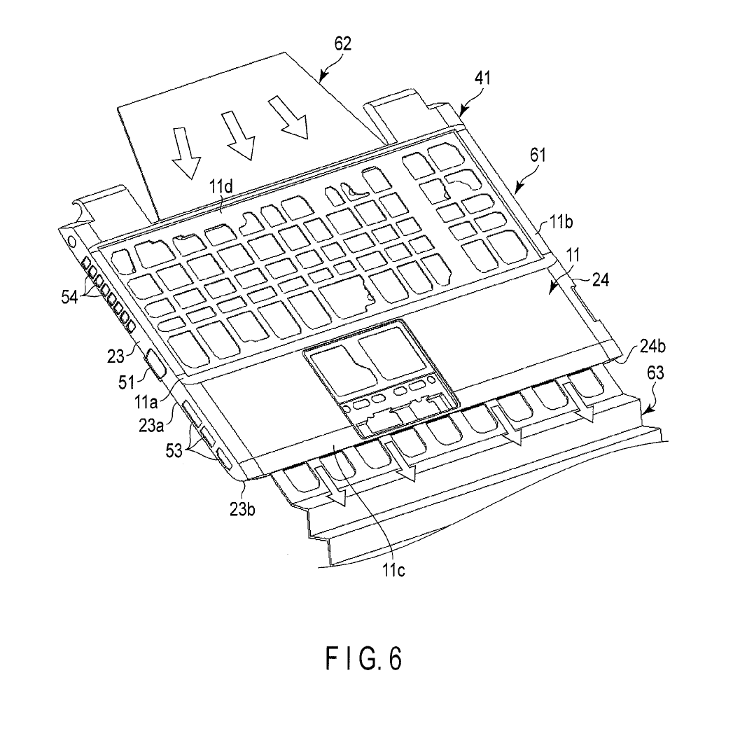

FIG. 6 is a diagram schematically illustrating an example of a method of manufacturing the upper cover 41. The upper cover 41 is manufactured by, for example, die casting with, for example, an aluminum alloy or a magnesium alloy. In FIG. 6, a white arrow indicates the flow of molten metal.

As shown in FIG. 6, a mold for forming the upper cover 41 includes a product portion 61 corresponding to the shape of the upper cover 41, an inflow gate 62, and an overflow 63. The product portion 61 is used to form the upper cover 41. The inflow gate 62 is a flow path through which the molten metal is guided to the product portion 61. The overflow 63 is provided opposite to the inflow gate 62. An initial material ejected from a casting machine or a material at the flow front of entrapped air flows into the overflow 63 so as not to remain in the product portion 61. After casting, the material solidified in the inflow gate 62 and the material solidified in the overflow 63 are cut.

In the case of a rectangular product, the molten metal flows in a direction substantially parallel to the short side of the product such that inflow resistance is reduced. As shown in FIG. 6, in this embodiment, the inflow gate 62 is connected to a region of the product portion 61 in which the rear end 11d of the upper wall 11 will be formed. The overflow 63 is connected to a region of the product portion 61 in which the front end 11c of the upper wall 11 will be formed.

In this way, the molten metal is injected from the rear end 11d toward the front end 11c of the upper wall 11 and flows substantially in parallel to the first and second side walls 23 and 24. The overflow 63 is provided substantially on the extension line of a region of the product portion 61 in which the upper wall 11 will be formed. In this way, the molten metal flowing into the region for forming the upper wall 11 can flow into the overflow 63 with low flow resistance.

As shown in FIG. 2, the lower cover 42 includes the lower wall 12, the front wall 21, and a portion of the rear wall 22. The lower cover 42 may be made of a metal or other materials, such as plastic. The lower wall 12 is an example of a “fourth wall”. The lower wall 12 is opposite to the upper wall 11 with a space therebetween. The first to third circuit boards 31, 32, and 33 and the units 34 and 35 are provided between the lower wall 12 and the upper wall 11. The lower wall 12 extends between the lower end 23a of the first side wall 23 and the lower end 24a of the second side wall 24 and is adjacent (for example, connected) to the lower end 23a of the first side wall 23 and the lower end 24a of the second side wall 24.

The lower wall 12 includes the left end 12a, the right end 12b, a front end 12c, and a rear end 12d. The left end 12a is an example of a “first end”. The right end 12b is an example of a “second end” and is opposite to the left end 12a. The left end 12a and the right end 12b extend substantially in parallel to each other.

The front end 12c and the rear end 12d extend in a direction crossing (for example, substantially perpendicular to) the left end 12a and the right end 12b. The front end 12c is an example of a “third end” and extends between the front edge of the left end 12a and the front edge of the right end 12b. The rear end 12d is an example of a “fourth end” and is opposite to the front end 12c. The rear end 12d extends between the rear edge of the left end 12a and the rear edge of the right end 12b.

As shown in FIG. 5, the first and second side walls 23 and 24 include a surface 65 (outer surface) and a receiving portion 66 (engaging portion) disposed more inside the housing 5 than the surface 65. The left end 12a and the right end 12b of the lower wall 12 come into contact with the receiving portion 66. Therefore, the left end 12a and the right end 12b of the lower wall 12 are disposed more inside the housing 5 than the surfaces 65 of the first and second side walls 23 and 24. In other words, the left end 12a and the right end 12b of the lower wall 12 are not exposed to the outside of the housing 5.

As shown in FIG. 5, conductive members 67, which are cushion members, are provided in the housing 5. The conductive member 67 is, for example, an EMI gasket. The conductive members 67 are interposed between the connectors 37, 38, and 38 and the lower wall 12, respectively. The conductive members 67 are disposed at a little distance from the first side wall 23. The conductive members 67 electrically connect the connectors 37, 38, and 39 to the lower wall 12.

The front wall 21 is an example of a “fifth wall”. As shown in FIGS. 1 and 2, the front wall 21 extends from the front end 12c of the lower wall 12 to the front end 11c of the upper wall 11 and is adjacent (for example, connected) to the front end 11c of the upper wall 11. For example, the front wall 21 extends in a direction crossing the lower wall 12. For example, the front wall 21 is provided over substantially the entire length of the front end 12c of the lower wall 12 and corresponds to substantially the entire length of the front end 11c of the upper wall 11.

The front wall 21 is provided in at least a portion of the space between the front end 23b of the first side wall 23 and the front end 24b of the second side wall 24. In this embodiment, the front wall 21 is provided over the entire region between the front end 23b of the first side wall 23 and the front end 24b of the second side wall 24 and covers the gap between the first side wall 23 and the second side wall 24.

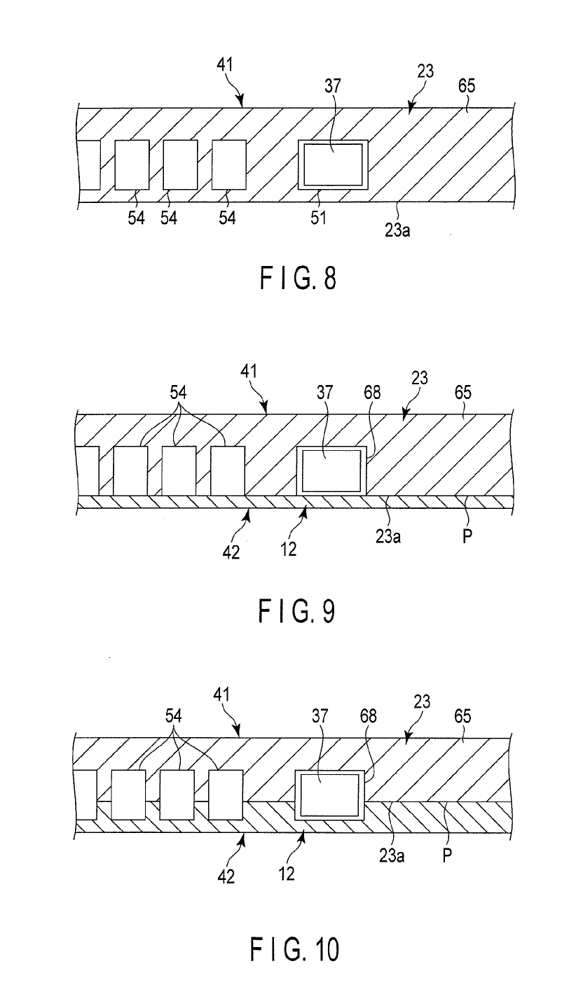

FIG. 8 is a diagram schematically illustrating the side surface of the housing 5 according to this embodiment. In this embodiment, the side surface of the housing 5 is formed by the first and second side walls 23 and 24. As described above, the left end 12a and the right end 12b of the lower wall 12 are disposed more inside the housing 5 than the surfaces 65 of the first and second side walls 23 and 24 and are not exposed to the side surface of the housing 5.

As shown in FIG. 8, portions of the first and second side walls 23 and 24 are disposed on sides of the connectors 37, 38, and 39. That is, in this embodiment, walls that reach the sides of the connectors 37, 38, and 39 is formed integrally with the upper wall 11.

FIGS. 9 and 10 show some modifications. As shown in FIGS. 9 and 10, the first and second side walls 23 and 24 reach sides of the connectors 37. As described above, the “opening area” and the “area through which a connector is exposed” are not limited to the through hole shown in FIG. 8, and may be a cutout portion 68 shown in FIGS. 9 and 10 which is formed along a portion of the outer shape of the connector 37.

In the structure shown in FIGS. 8, 9, and 10, a parting line P between the upper cover 41 and the lower cover 42 is not present between the exhaust hole 54 and the upper surface 11u (operation surface) of the upper wall 11. The parting line P is a division line between the upper cover 41 and the lower cover 42 and is an example of the boundary between the upper cover 41 and the lower cover 42.

Next, the assembly of the first unit 2 will be described.

As shown in FIG. 2, the first unit 2 is assembled by turning the upper cover 41 upside down and sequentially attaching the first to third circuit boards 31, 32, and 33, and the units 34 and 35 to the inner surface of the upper cover 41. Specifically, as represented by a black arrow in FIG. 2, the first circuit board 31 is combined with the first side wall 23 from the upper side in the oblique direction and the first connector 37 is inserted into the first opening 51. After or at the same time as the first connector 37 is inserted into the first opening 51, the first circuit board 31 is substantially parallel to the upper wall 11 and is fixed to the bosses 44 of the upper wall 11 by, for example, the screws 45.

Similarly, the second circuit board 32 is combined with the second side wall 24 from the upper side in the oblique direction and the second connectors 38 are inserted into the second openings 52. After or at the same time as the second connectors 38 are inserted into the second openings 52, the second circuit board 32 is substantially parallel to the upper wall 11 and is fixed to the bosses 44 of the upper wall 11 by, for example, the screws 45.

Similarly, the third circuit board 33 is combined with the first side wall 23 from the upper side in the oblique direction and the third connectors 39 are inserted into the third openings 53. After or at the same time as the third connectors 39 are inserted into the third openings 53, the third circuit board 33 is substantially parallel to the upper wall 11 and is fixed to the bosses 44 of the upper wall 11 by the screws 45. The units 34 and 35 are combined with the upper wall 11 from the upper side and are fixed to the bosses 44 of the upper wall 11 by, for example, the screws 45.

Finally, the lower cover 42 is attached to the upper cover 41. Specifically, the lower cover 42 turned upside down is combined with the upper cover 41 from the upper side and is fixed to the upper cover 41 by, for example, screws. In this way, the assembly of main parts of the first unit 2 is completed.

According to the above-mentioned structure, it is possible to improve assemblability.

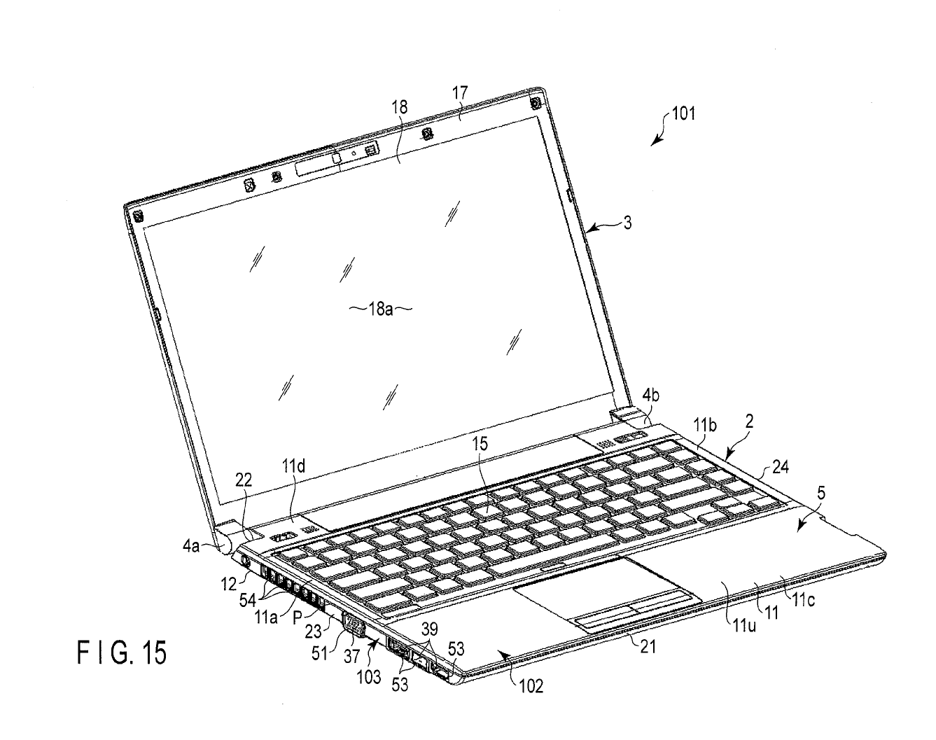

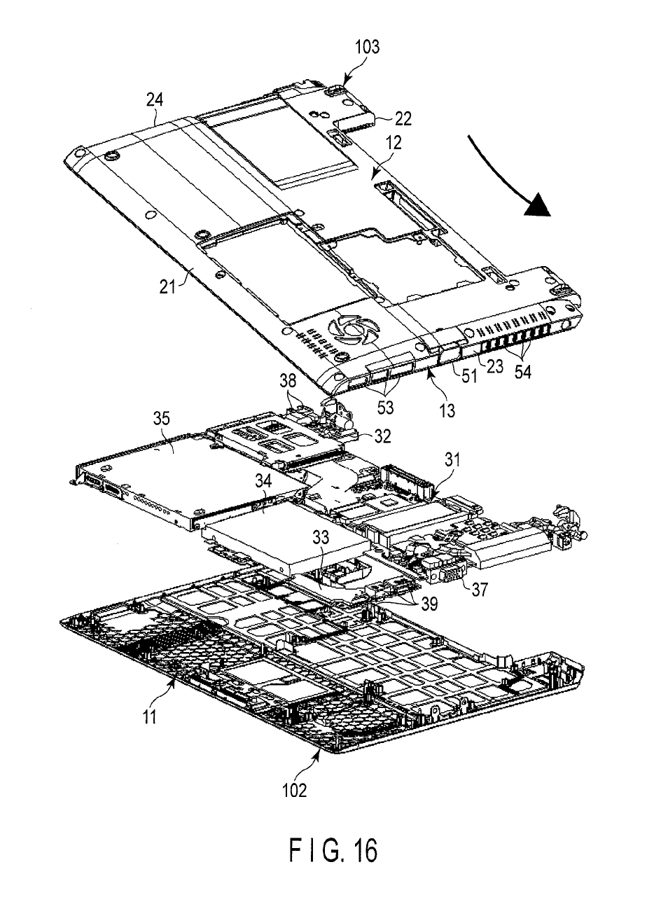

For comparison, FIGS. 15, 16, and 17 show another electronic apparatus 101. The electronic apparatus 101 includes an upper cover 102 and a lower cover 103. As shown in FIG. 16, the lower cover 103 includes a lower wall 12, a first side wall 23, a second side wall 24, a front wall 21, and a rear wall 22. That is, in the electronic apparatus 101, the first and second side walls 23 and 24 and the lower wall 12 are integrated with each other to form the lower cover 103. In other words, the lower cover 103 has a box shape that includes the lower wall 12 and four walls provided in four ends 12a, 12b, 12c, and 12d of the lower wall 12 and has an open top. The upper cover 102 has a plate shape including only the upper wall 11.

In the assembly of the electronic apparatus 101, the first to third circuit boards 31, 32, and 33 and the units 34 and 35 are sequentially attached to the inner surface of the upper cover 102 turned upside down. The first to third circuit boards 31, 32, and 33 and the units 34 and 35 are mounted and fixed to the inner surface of the upper wall 11 from the upper side.

After the first to third circuit boards 31, 32, and 33 and the units 34 and 35 are fixed to the upper wall 11, the lower cover 103 is attached to the upper cover 102. In the electronic apparatus 101, since the openings 51, 52, and 53 for connectors are provided in the lower cover 42, it is not possible to simply attach the lower cover 103 to the upper cover 102 from the upper side. Therefore, as represented by a black arrow in FIG. 16, the lower cover 103 is inclined and it is necessary to couple the lower cover 103 to the upper cover 102 while inserting the connectors 37 and 39 into the openings 51 and 53 of the first side wall 23. In this assembly process, the degree of difficulty in assembly is high and assemblability is reduced. In particular, it is difficult to attach a relatively large member, such as the lower cover 103, while being obliquely inclined.

In the electronic apparatus 101, the second connector 38 is provided in the right end portion of the housing 5 and the opening 52 for the connector 38 is provided in the second side wall 24 which is formed integrally with the lower cover 42. As such, the connectors 37, 38, and 39 are separately provided in the left and right portions of the housing 5 and the openings 51, 52, and 53 are separately provided in the left and right side walls 23 and 24 of the lower cover 103. In this case, it is necessary to insert the connector 38 into the opening 52 of the second side wall 24 after the connectors 37 and 39 are inserted into the openings 51 and 53 of the first side wall 23. This operation is very difficult. It is necessary to form the housing with separate components corresponding to the left and right connectors, if required.

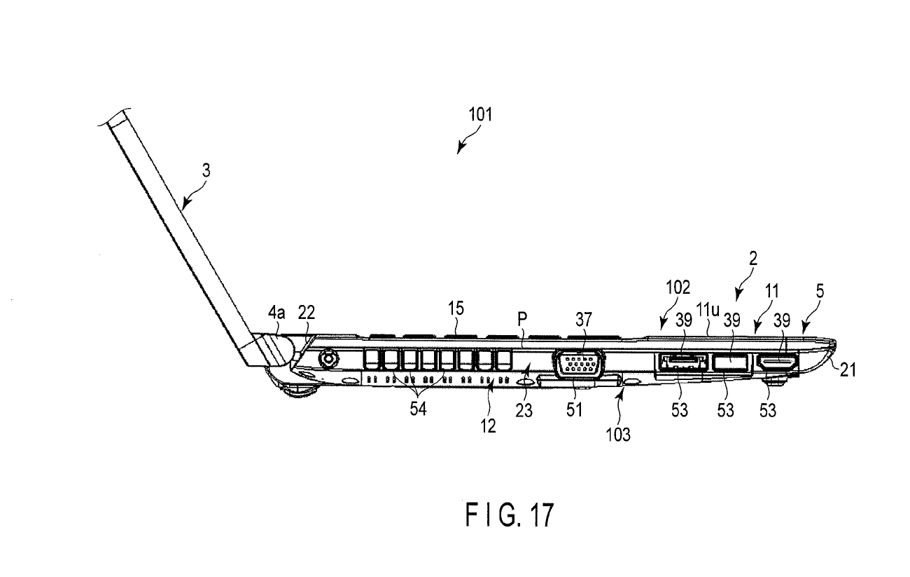

As shown in FIGS. 15 and 17, in the electronic apparatus 101, there is a parting line P between the upper cover 41 and the lower cover 42 in the side surface of the product. The parting line P is formed in a substantially straight shape in order to ensure the strength of the upper cover 41 and the lower cover 42. For example, the leading end of each of the left end 11a and the right end 11b of the upper wall 11 is bent toward the lower wall 12 in order to improve the appearance of the peripheral edge of the upper wall 11. Therefore, the parting line P is disposed slightly below the upper surface 11u of the upper wall 11.

Therefore, the openings 51, 52, and 53 for connectors or the exhaust holes 54 need to be disposed below the parting line P. For example, when a tall connector, such as an RGB connector or a RJ45 connector, is provided, the connector protrudes from the lower surface of the product, which is not preferable in terms of the design. In addition, the size of the exhaust hole 54 is limited by the parting line P and it is difficult to provide a large exhaust hole 54.

In contrast, in the electronic apparatus 1 according to this embodiment, the upper cover 41 includes the upper wall 11 and the side wall 23 that extends from the end of the upper wall 11 and is provided with the opening 51 through which the connector 37 is exposed. According to this structure, since the opening 51 of the side wall 23 is provided in the upper cover 41, it is possible to simply insert the connector 37 into the opening 51 by turning the upper cover 41 upside down. Therefore, it is possible to improve the assemblability of the electronic apparatus 1.

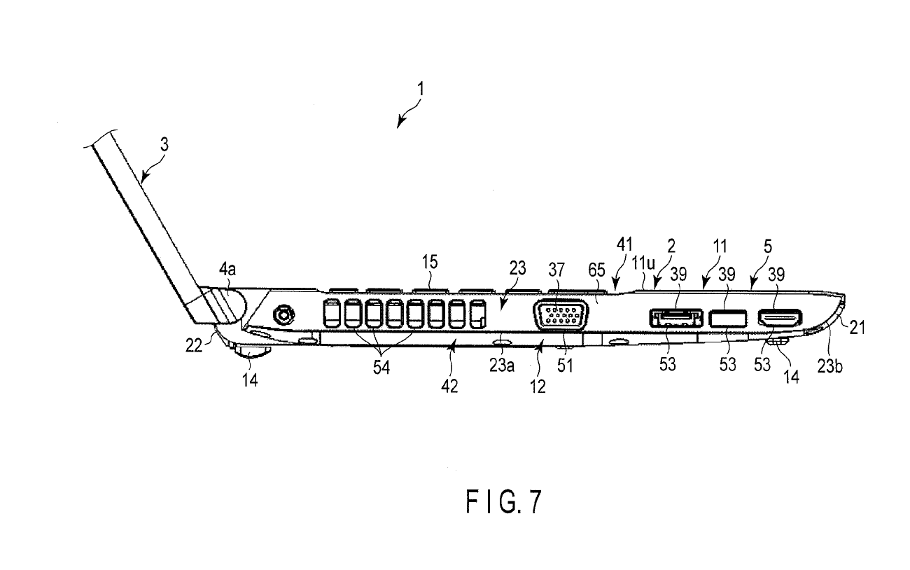

In addition, according to this embodiment, as shown in FIGS. 1 and 7, since the parting line P is not present between the openings 51, 52, and 53 for connectors and the upper wall 11, flexibility in the design of the openings 51, 52, and 53 for connectors is improved. Therefore, even when a tall connector 37 is provided, it is possible to suppress the connector 37 from protruding from the lower surface of the product. In this way, it is possible to reduce the thickness of the electronic apparatus 1.

According to this embodiment, as shown in FIGS. 1 and 7, since there is no parting line P between the exhaust hole 54 and the upper wall 11, flexibility in the design of the exhaust hole 54 is improved. That is, it is possible to increase the size of the exhaust hole 54 without being limited by the parting line P. When the size of the exhaust hole 54 increases, the amount of air discharged increases. Therefore, it is possible to improve the cooling performance of the electronic apparatus 1.

In this embodiment, the first and second side walls 23 and 24 are provided integrally with the upper wall 11. According to this structure, the first and second side walls 23 and 24 function as beams and the high strength (rigidity) of the upper cover 41 is ensured. Therefore, even when the lower cover 42 is made of a material, such as plastic with a rigidity less than that of metal, it is possible to ensure a sufficient strength of the housing 5. When the lower cover 42 can be made of plastic, it is possible to reduce the costs of the electronic apparatus 1.

The electronic apparatus 1 according to this embodiment includes the upper cover 41 and the lower cover 42. The upper cover 41 includes the upper wall 11, the first side wall 23 that extends from one end of the upper wall 11 and is provided with a region in which the connector 37 is exposed, and the second side wall 24 that extends from the other end of the upper wall 11 and is opposite to the first side wall 23. The lower cover 42 includes the lower wall 12 opposite to the upper wall 11 and the front wall 21 that extends from the end of the lower wall 12 toward the upper wall 11 and is disposed in at least a portion of the space between the first side wall 23 and the second side wall 24. According to this structure, since the front wall 21 rising from the lower wall 12 functions as a beam for reinforcing the lower wall 12, the strength of the lower cover 42 is improved.

In this embodiment, the connectors 37, 38, and 39 are mounted on the circuit boards 31, 32, and 33 smaller than the lower wall 12. In the assembly of the first unit 2, the circuit boards 31, 32, and 33 are obliquely inclined and the connectors 37, 38, and 39 are inserted into the openings 51, 52, and 53 provided in the side walls 23 and 24. Since the circuit boards 31, 32, and 33 are relatively small, it is possible to simply incline and attach the circuit boards 31, 32, 33. Therefore, it is possible to improve the assemblability of the electronic apparatus 1.

In this embodiment, the upper cover 41 is opened between the first side wall 23 and the second side wall 24 in the direction along the upper wall 11. Then, the front wall 21 of the lower cover 42 covers the space between the first side wall 23 and the second side wall 24. According to this structure, it is possible to simplify the structure of the upper cover 41 and thus improve the manufacturability of the housing 5.

In this embodiment, the upper wall 11 includes the bosses 44 that protrude from the inner surface of the upper wall 11 to the lower wall 12. The circuit board 31 is attached to the bosses 44. According to this structure, it is possible to easily attach the circuit board 31 to the upper wall 11.

In this embodiment, the second opening 52 is provided in the second side wall 24. The second connector 38 mounted on the second circuit board 32 is inserted into the second opening 52. In this structure, since the first and second connectors 37 and 38 are mounted on different members, it is possible to separately perform an operation of inserting the first connector 37 into the opening 51 of the first side wall 23 and an operation of inserting the second connector 38 into the opening 52 of the second side wall 24.

Therefore, it is possible to smoothly insert the first and second connectors 37 and 38 into the first and second openings 51 and 53, respectively. As a result, it is possible to improve the assemblability of the electronic apparatus 1.

In this embodiment, the upper cover 41 is manufactured by die casting. Molten metal is injected from the rear end 11d toward the front end 11c of the upper wall 11 and flows substantially in parallel to the first and second side walls 23 and 24. According to this structure, the first and second side walls 23 and 24 rising from the upper wall 11 are less likely to hinder the flow of the molten metal and castability is improved.

In this embodiment, no rising wall is provided in the front end 11c of the upper wall 11 and the overflow 63 is provided on the extension line of a region of the product portion 61 in which the upper wall 11 will be formed. Therefore, for example, a flow obstacle is less likely to occur during casting and the flow of molten metal is not curved. As a result, the quality of casting is improved.

### SECOND EMBODIMENT

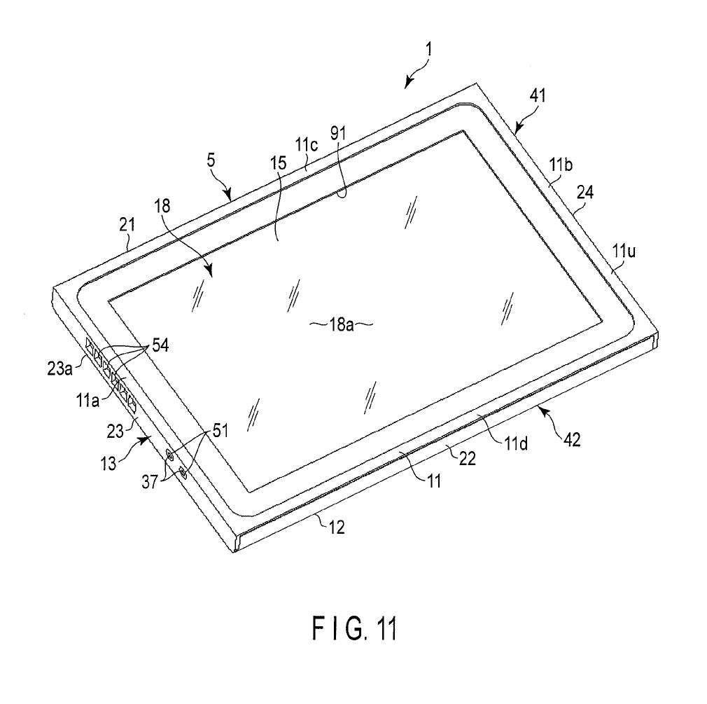

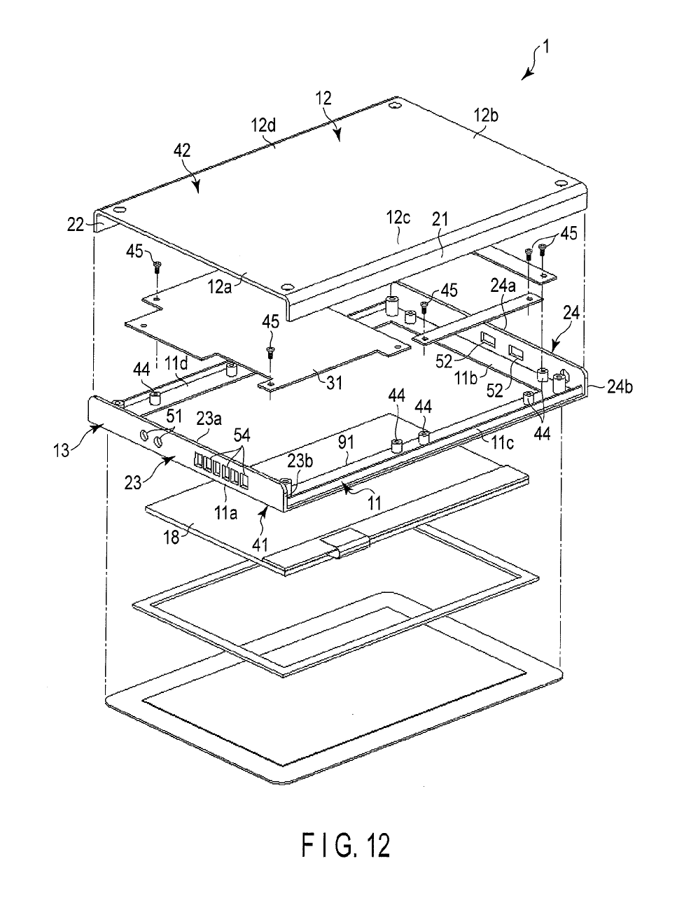

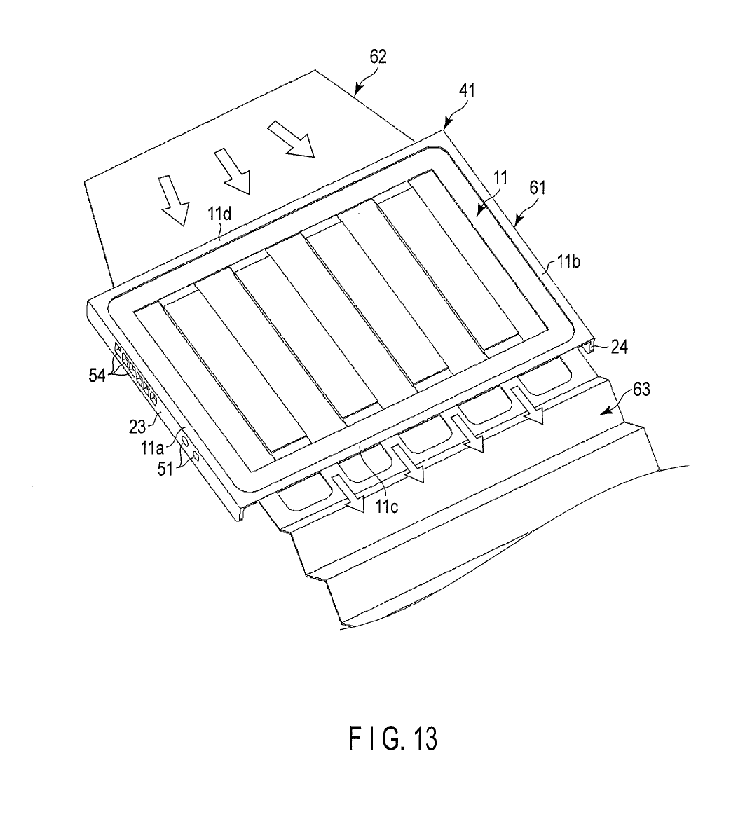

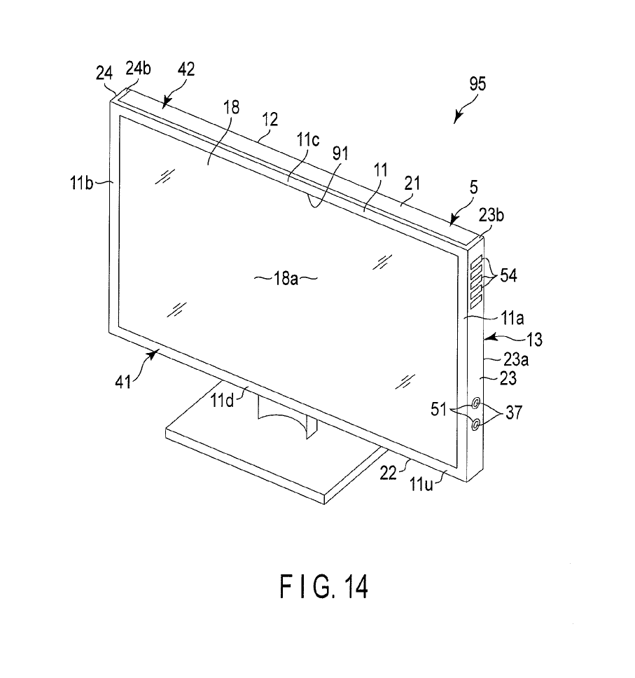

Next, an electronic apparatus 1 according to a second embodiment will be described with reference to FIGS. 11, 12, and 13. In the second embodiment, components having the same or similar functions as those in the first embodiment are denoted by the same reference numerals and a description thereof will not be repeated. In addition, structures other than the following structures are the same as those in the first embodiment.

As shown in FIGS. 11, 12, and 13, the electronic apparatus 1 according to this embodiment is a portable electronic apparatus and is, for example, a slate PC. For example, the user holds the electronic apparatus 1 in the hand and uses it. The electronic apparatus 1 includes a housing 5 and a display device 18 provided in the housing 5. The housing 5 includes a front wall 11, a rear wall 12, and a peripheral wall 13.

An opening 91 through which a display screen 18a of the display device 18 is exposed is provided in the front wall 11. A touch panel that receives an input from the user is provided on the display device 18. The display screen 18a is an example of an “input portion” (i.e., input receiving portion). A front surface 11u of the front wall 11 from which the display screen 18a is exposed is an example of an “operation surface”. The peripheral wall 13 includes an upper wall 21, a lower wall 22, a first side wall 23, and a second side wall 24. A first cover 41 includes a front wall 11, a first side wall 23, and a second side wall 24. A second cover 42 includes a rear wall 12, an upper wall 21, and a lower wall 22. The front wall 11, the first side wall 23, the second side wall 24, the rear wall 12, and the upper wall 21 (or the lower wall 22) are examples of a “first wall”, a “second wall”, a “third wall”, a “fourth wall”, and a “fifth wall”, respectively.

According to this structure, similarly to the first embodiment, it is possible to improve the assemblability of the electronic apparatus 1.

### THIRD EMBODIMENT

Next, a television 95 according to a third embodiment will be described with reference to FIG. 14. In the third embodiment, components having the same or similar functions as those in the first and second embodiments are denoted by the same reference numerals and a description thereof will not be repeated. In addition, structures other than the following structures are the same as those in the first embodiment.

As shown in FIG. 14, the television 95 includes a housing 5 and a display device 18 provided in the housing 5. The housing 5 includes a front wall 11, a rear wall 12, and a peripheral wall 13. A receiver that receives an input from a remote controller is provided behind the front wall 11. The user operates the remote controller toward the front wall 11, thereby operating the television 95. In this embodiment, a front surface 11u of the front wall 11 is an example of an “operation surface.”

According to this structure, similarly to the first embodiment, it is possible to improve the assemblability of the television 95 as an electronic apparatus.

The embodiments are not limited to the above-described embodiments, and the components of the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a first member comprising a first wall, a second wall, and a third wall, the first wall comprising an operation surface, a first end, a second end opposite to the first end, and a third end configured differently than the first end and the second end, the second wall extending from the first end and comprising a first opening, and the third wall extending from the second end and facing the second wall;
a second member comprising a fourth wall and a fifth wall, the fourth wall facing the first wall and adjacent to an end of the second wall and an end of the third wall, the fifth wall extending from an end of the fourth wall to the third end of the first wall; and
a circuit board smaller than the fourth wall, the circuit board between the first wall and the fourth wall, the circuit board configured to attach to the first member, and the circuit board comprising a connector configured to be inserted into the first opening.

2. The electronic apparatus of claim 1,
wherein the first member is open between the second wall and the third wall in a direction along the first wall, and
the fifth wall corresponds to substantially the entire length of the third end of the first wall and is configured to cover a space between the second wall and the third wall.

3. The electronic apparatus of claim 1,
wherein the first wall further comprises a boss protruding from an inner surface of the first wall, and
the circuit board is configured to attach to the boss.

4. The electronic apparatus of claim 1, further comprising a second circuit board separate from the circuit board and configured to attach to the first member,
wherein the third wall comprises a second opening, and the second circuit board comprises a second connector configured to be inserted into the second opening.

5. The electronic apparatus of claim 1,
wherein at least one of the second wall and the third wall comprises an exhaust hole, and
a boundary between the first member and the second member is not present between the exhaust hole and the operation surface.

6. The electronic apparatus of claim 1, wherein the first member is die casted.

7. The electronic apparatus of claim 6,
wherein the first member further comprises a fourth end opposite to the third end, and
the first member comprises molten metal formed by injecting molten metal from the fourth end toward the third end in such a manner that the molten metal flows substantially parallel to the second wall and the third wall.

8. The electronic apparatus of claim 6,
wherein the first member is formed by a mold, the mold comprising a product portion corresponding to a shape of the first member, an inflow gate connected to a region of the product portion in which the fourth end is formed, and an overflow connected to a region of the product portion in which the third end is formed, and
the overflow is located substantially on an extension line of a region of the product portion in which the first wall is formed.

9. An electronic apparatus comprising:
a first member manufactured by die casting and comprising a first wall and a second wall, the first wall comprising an operation surface, the second wall extending from an end of the first wall and comprising an opening area;
a second member attached to the first member; and
a circuit board between the first member and the second member, the circuit board comprising a connector configured to be exposed through the opening area.

10. An electronic apparatus comprising:
a circuit board comprising a connector;
a first member comprising a first wall, a second wall, and a third wall, the first wall comprising an operation surface, a first end, and a second end opposite to the first end, the second wall extending from the first end and comprising an area configured to expose the connector, the third wall extending from the second end and facing the second wall; and
a second member comprising a fourth wall and a fifth wall, the fourth wall facing the first wall, the fifth wall extending from an end of the fourth wall toward the first wall,
wherein the circuit board is between the first wall and the fourth wall.
